(19) United States
(12) Patent Application Publication
(10) Pub. No.: US 2023/0411181 A1
(43) Pub. Date: Dec. 21, 2023

(54) VERIFICATION METHOD FOR DEVICE CHIPS

(71) Applicant: DISCO CORPORATION, Tokyo (JP)

(72) Inventor: Masaru NAKAMURA, Tokyo (JP)

(21) Appl. No.: 18/328,988

(22) Filed: Jun. 5, 2023

(30) Foreign Application Priority Data
Jun. 20, 2022 (JP) 2022-098739

(51) Int. Cl. H01L 21/67; H01L 21/683; H01L 21/66

(52) U.S. Cl. CPC H01L 21/67092; H01L 21/6836; H01L 22/12; H01L 2221/68327

(57) ABSTRACT

A verification method for device chips, includes a providing step of providing a wafer having a front surface with a plurality of devices formed thereon and demarcated by streets, the devices including non-defective devices and defective devices that are distinguished from each other based on an electrical characteristic, a dividing step of dividing the wafer into individual device chips along the streets, a defective device chip extracting step of extracting defective device chips from the individual device chips, the defective device chips corresponding to the defective devices and being defective in the electrical characteristic, and a verification step of verifying a physical characteristic of each of the extracted defective device chips.

### BACKGROUND OF THE INVENTION

### Field of the Invention

The present invention relates to a verification method for device chips obtained by dividing a wafer.

### Description of the Related Art

A wafer that has a front surface with a plurality of devices such as integrated circuits (ICs) or large-scale integration (LSI) circuits formed thereon and demarcated by a plurality of intersecting streets is divided into individual device chips by a cutting apparatus or a laser processing apparatus, and the divided device chips are used in electronic equipment such as mobile phones or personal computers.

Along with downsizing and thinning of electronic equipment, there is also a growing demand for downsizing and thinning of device chips in recent years. When a wafer is processed using the above-described cutting apparatus, laser processing apparatus, or the like, processing strain may be formed in the wafer. If this processing strain remains in device chips obtained by dividing the wafer, the device chips are lowered in one or more physical characteristics, thereby leading to such a problem that reliability of electronic equipment with these device chips adopted therein is reduced.

With a view to addressing the above-described problem, a countermeasure is taken to avoid adopting device chips, which have been divided from a wafer including one or more device chips found to have a problem in a physical characteristic such as flexural strength or impact strength, in products by verifying their physical characteristic before they are incorporated in electronic equipment such as smartphones (see, for example, Japanese Patent Laid-open No. 2010-160074 and Japanese Patent Laid-open No. 2020-094833).

### SUMMARY OF THE INVENTION

In the above-described verification of the physical characteristic of the device chips, what is generally called sampling check is performed to further ensure the avoidance of adoption of device chips, which have a problem in the physical characteristic, in electronic equipment. Described specifically, the verification is performed on the above-described physical characteristic such as flexural strength or impact strength by dividing the wafer, on which the devices to be actually provided as products are formed, into individual device chips, and then extracting some of the device chips at random after the division. If no problem is determined to exist in the physical characteristic of the device chips by the verification, the device chips divided from the wafer are used in electronic equipment.

As the above-described verification method is however applied at a cost of wasting a plurality of non-defective device chips that are usable as products, a problem arises in that it is uneconomical.

The present invention therefore has as an object thereof the provision of a verification method for devices chips, which can avoid such wasting of non-defective device chips.

In accordance with an aspect of the present invention, there is provided a verification method for device chips, including a providing step of providing a wafer having a front surface with a plurality of devices formed thereon and demarcated by a plurality of intersecting streets, the devices including non-defective devices and defective devices that are distinguished from each other based on an electrical characteristic, a dividing step of, after the providing step, dividing the wafer into individual device chips along the streets, a defective device chip extracting step of extracting defective device chips from the individual device chips, the defective device chips corresponding to the defective devices and being defective in the electrical characteristic, and a verification step of verifying a physical characteristic of each of the extracted defective device chips.

Preferably, the verification method may further include a determination step of determining based on results of the verification step whether or not to transfer non-defective device chips out of the individual device chips to a subsequent step, the non-defective device chips corresponding to the non-defective devices and being non-defective in the electrical characteristic. Preferably, the wafer may be positioned in an opening of an annular frame and be integrated with the annular frame via a dicing tape. Preferably, the dividing step may be performed by one of a cutting blade, a laser beam, plasma, dicing before grinding (DBG), or stealth dicing before grinding (SDBG).

According to the verification method of the present invention, it is possible to avoid wasting of some of non-defective device chips even in the case where device chips divided from a wafer are verified in a physical characteristic such as flexural strength or impact strength before their incorporation in electronic equipment such as smartphones, thereby eliminating the problem that the verification method of the related art is uneconomical.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating how a providing step of a verification method according to an embodiment of the present invention is performed;

FIG. 2 is a perspective view illustrating how a dividing step of the verification method is performed;

FIG. 3 is a perspective view of a pickup apparatus suitable for performing a defective device chip extracting step of the verification method;

FIG. 4 is a perspective view illustrating how defective device chips are extracted from a wafer in the defective device chip extracting step; and

FIG. 5 is a cross-sectional view illustrating how a verification step of the verification method is performed.

### DETAILED DESCRIPTION OF THE PREFERRED EMBODIMENT

With reference to the attached drawings, a description will hereinafter be made in detail about a verification method according to an embodiment of the present invention for device chips.

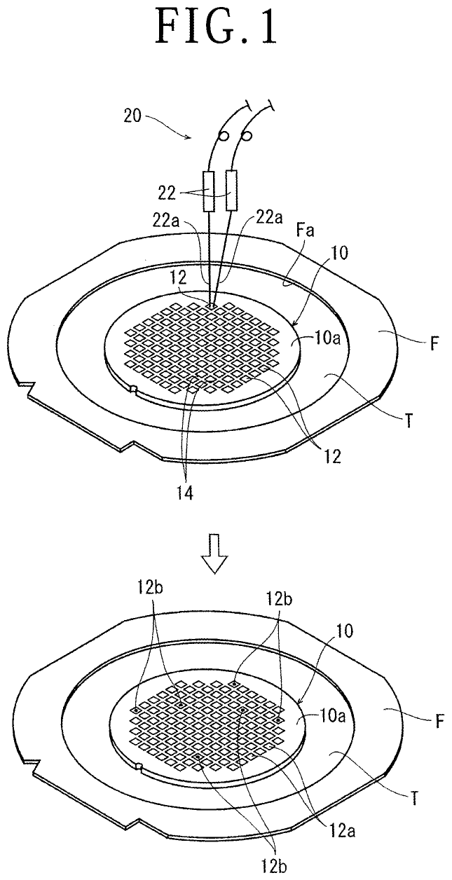

When performing the verification method of this embodiment for device chips, a providing step is first performed to provide a wafer in which non-defective devices and defective devices have been distinguished from each other based on an electrical characteristic. FIG. 1 illustrates an unprocessed wafer 10 to which the verification method of this embodiment is to be applied. The wafer 10 has a plurality of devices 12 formed on a front surface 10a thereof and demarcated by streets 14. The wafer 10 is received in an opening Fa of an annular frame F and is bonded and integrated with the annular frame F via a dicing tape T.

On the wafer 10, an electrical characteristic test is conducted such that non-defective devices and defective devices are distinguished from each other based on an electrical characteristic. The electrical characteristic test is conducted, for example, as illustrated in FIG. 1. Described specifically, terminals 22 of a prober 20, which is to conduct the electrical characteristic test, are positioned relative to the devices 12 formed on the front surface 10a of the wafer 10, and tip portions 22a of the respective terminals 22 are brought into contact with electrodes (not illustrated) of each device 12 to conduct a continuity test of the device 12, so that the device 12 under testing is tested whether or not its electrical characteristic is normal. Based on the results of the test, the device 12 under testing is determined whether it is a non-defective device 12a normal in the electrical characteristic or a defective device 12b abnormal in the electrical characteristic. The above-described electrical characteristic test is conducted on all the devices 12 formed on the front surface 10a of the wafer 10, and as illustrated in a lower part of FIG. 1, a marking is applied with an ink of a predetermined color (for example, red) to front surfaces of the defective devices 12b, so that the non-defective devices 12a and the defective devices 12b can be distinguished from each other. A description will hereinafter be made assuming that, on the wafer 10 illustrated in the figure, six defective devices 12b which are defective in the electrical characteristic exist in total, and the remainder are the non-defective devices 12a which are normal in the electrical characteristic. The providing step of providing the wafer 10, in which the non-defective devices 12a and the defective devices 12b have been distinguished from each other, has now been completed. It is however to be noted that the present invention is not limited to applying the marking to the defective devices 12b, and coordinates on the wafer 10, the coordinates enabling specification of the position of each defective device 12b, may be stored in a controller (not illustrated).

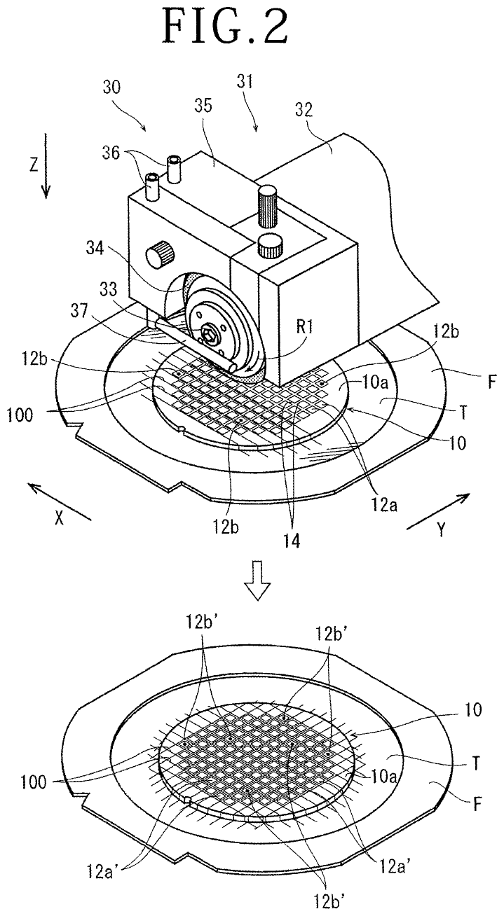

After the completion of the above-described providing step, a dividing step is performed to divide the devices 12 of the wafer 10 into individual device chips along the streets 14. When performing the dividing step, a desired dividing method can be selected from a variety of dividing methods. In this embodiment, the wafer 10 provided through the above-described providing step is transferred to a cutting apparatus 30 (only part of which is illustrated) illustrated in FIG. 2, and the dividing step is performed.

The cutting apparatus 30 includes a chuck table (not illustrated) that holds the wafer 10 under suction and a cutting unit 31 that cuts the wafer 10 held under suction on the chuck table. The chuck table is configured to be rotatable and includes an X-axis feed mechanism (not illustrated) that feeds the chuck table for processing in an X-axis direction indicated by arrow X in the figure. The cutting unit 31 includes a spindle housing 32 arranged in a Y-axis direction indicated by arrow Y in the figure, a spindle 33 rotatably held in the spindle housing 32, and an annular cutting blade 34 held on a distal end of the spindle 33, and also includes a Y-axis feed mechanism (not illustrated) that feeds the cutting blade 34 for indexing in the Y-axis direction. The spindle 33 is rotationally driven by a spindle motor (not illustrated). On a distal end portion of the spindle housing 32, a blade cover 35 is arranged covering the spindle 33. Arranged through and on the blade cover are cutting water inlets 36 through which cutting water is introduced, and cutting water ejection nozzles 37 that eject the cutting water, which has been introduced from the cutting water inlets 36, to locations where the wafer 10 is subjected to cutting processing by the cutting blade 34.

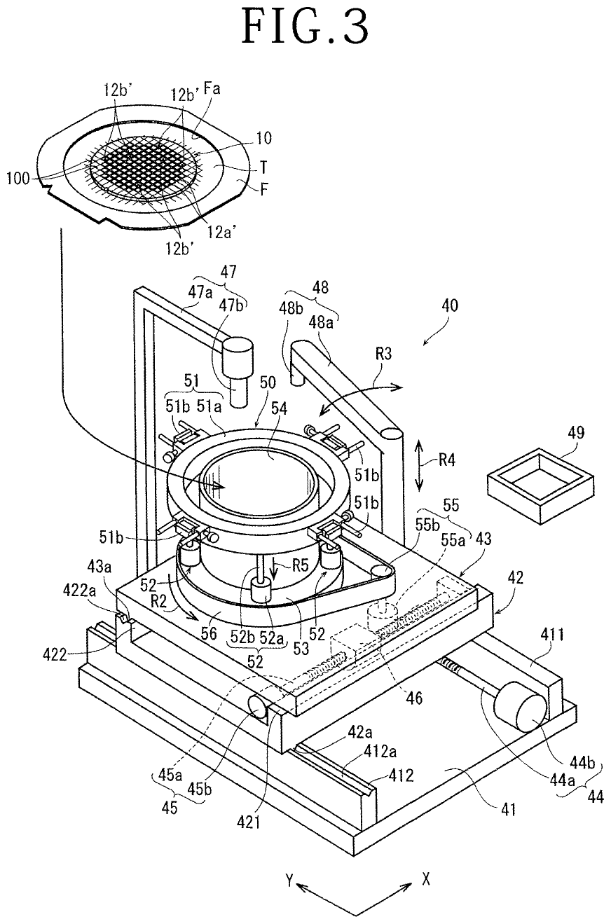

When performing the dividing step, the wafer 10 is first placed and held under suction on the chuck table of the cutting apparatus 30 with the front surface 10a directed upward. Using an alignment unit (not illustrated), the streets 14 that extend in a first direction of the wafer 10 are brought into alignment with the X-axis direction, and also into alignment with the cutting blade 34. Next, the cutting blade 34 is rotated at high speed in a direction indicated by arrow R1, is positioned over predetermined one of the streets 14 aligned with the X-axis direction and extending in the first direction, and is caused to cut into the wafer 10 in a Z-axis direction indicated by arrow Z from a side of the front surface 10a, and at the same time, the chuck table is fed for processing in the X-axis direction to form a dividing groove 100 that divides the wafer 10. Further, the Y-axis feed mechanism is operated to feed the cutting blade 34 of the cutting unit 31 for indexing to above unprocessed one of the streets 14, the unprocessed street 14 being adjacent in the Y-axis direction to the above-described predetermined street 14 along which the dividing groove 100 has been formed, and another dividing groove 100 is then formed as in the above. By repeating these operations, dividing grooves 100 are formed along all the streets 14 that extend in the first direction. Next, the chuck table is rotated 90 degrees, the streets 14 that extend in a second direction orthogonal to the first direction along which the dividing grooves 100 have been formed beforehand are brought into alignment with the X-axis direction, and the above-described cutting processing is performed along all the streets 14 newly aligned with the X-axis direction, so that dividing grooves 100 are formed along all the streets 14 formed on the wafer 10. The dividing step has now been completed. Reference is next made to a lower part of FIG. 2. By performing the dividing step as described above, the wafer 10 is divided along the streets 14 into non-defective device chips 12a′ that are normal in the electrical characteristic and defective device chips 12b′ that are defective in the electrical characteristic. After the above-described performance of the dividing step, the divided wafer 10 is transferred to a pickup apparatus 40, which is illustrated in FIG. 3, in order to perform a defective device chip extracting step to extract the defective device chips 12b′.

The pickup apparatus 40 illustrated in FIG. 3 includes a base 41, a first table 42 arranged on the base 41 movably in a Y-axis direction indicated by arrow Y, a second table 43 arranged on the first table 42 movably in an X-axis direction that is indicated by arrow X and is orthogonal to the Y-axis direction, a detector 47, a pickup instrument 48, and an expansion unit 50. The base 41 is formed in a rectangular shape, and on upper surfaces of opposite side portions in the X-axis direction of the base 41, two guide rails 411 and 412 are arranged parallel to each other along the Y-axis direction. In an upper surface of one of the guide rails, that is, the guide rail 412, on the base 41, a guide groove 412a is formed with a V-shaped transverse cross-section.

On a lower surface of one of side portions in the X-axis direction of the first table 42, a guided rail 42a is disposed for slidable fitting engagement with the guide groove 412a formed in the above-described guide rail 412. On upper surfaces of opposite side portions in the Y-axis direction of the first table 42, two guide rails 421 and 422 are arranged parallel to each other along the X-axis direction. In an upper surface of one of the guide rails, that is, the guide rail 422, on the first table 42, a guide groove 422a is formed with a V-shaped transverse cross-section.

The first table 42 configured as described above is arranged over the base 41, with the above-described guided rail 42a fitted in the guide groove 412a formed in the one guide rail, that is, the guide rail 412, of the base 41, and with a lower surface of the other side portion mounted on the other guide rail, that is, the guide rail 411, of the base 41. On the base 41, a first moving mechanism 44 is arranged to move the first table 42 in the Y-axis direction indicated by arrow Y along the guide rails 411 and 412 disposed on the base 41. The first moving mechanism 44 includes an externally threaded rod 44a arranged parallel to the guide rail 411 disposed on the base 41 and a pulse motor 44b connected to an end of the externally threaded rod 44a to rotationally drive the externally threaded rod 44a, and the externally threaded rod 44a is in threaded engagement with an internally threaded block (not illustrated) disposed on a lower surface of the first table 42.

The above-described second table 43 is formed in a rectangular shape as illustrated in FIG. 3, and on a central portion thereof, includes the expansion unit 50 to expand the wafer 10 held on the annular frame F. On a lower surface of one of side portions in the Y-axis direction of the second table 43, a guided rail 43a is disposed for slidable fitting engagement with the guide groove 422a formed in the guide rail 422 disposed on the first table 42. The second table 43 configured as described above is arranged over the first table 42, with the above-described guided rail 43a fitted in the guide groove 422a formed in the one guide rail, that is, the guide rail 422, of the first table 42, and with a lower surface of the other side portion mounted on the other guide rail, that is, the guide rail 421, disposed on the first table 42. On the first table 42, a second moving mechanism 45 is arranged to move the second table 43 in the X-axis direction along the guide rails 421 and 422 disposed on the first table 42. The second moving mechanism 45 includes, as illustrated in FIG. 3, an externally threaded rod 45a (indicated by dashed lines) arranged parallel to the guide rail 421 disposed on the first table 42 and a pulse motor 45b connected to an end of the externally threaded rod 45a to rotationally drive the externally threaded rod 45a, and the externally threaded rod 45a is in threaded engagement with an internally threaded block 46 (indicated by dashed lines) disposed on a lower surface of the second table 43.

The expansion unit 50 is means for bringing the individual device chips into a state suited for being picked up from the wafer 10 by expanding the dicing tape T located between the wafer 10, which is held on the annular frame F, and the annular frame F, and widening spacings between adjacent ones of the non-defective device chips 12a′ and defective device chips 12b′. The expansion unit 50 includes a frame holding unit 51 that holds the annular frame F with the wafer 10 supported thereon, and tape expanding units 52 that expand the dicing tape T bonded to the annular frame F which is held by the frame holding unit 51.

The frame holding unit 51 includes a frame holding member 51a formed in an annular shape to hold the above-described annular frame F, and a plurality (four in this embodiment) of clamps 51b arranged as fixing means at equal intervals on an outer periphery of the frame holding member 51a. The frame holding member 51a is formed flat at an upper surface thereof, and the annular frame F placed on the upper surface of the frame holding member 51a is gripped by the clamps 51b and fixed on the upper surface on the frame holding member 51a.

On an inner side of the frame holding member 51a, a cylindrical expansion drum 54 fixed on a circular base 53 is arranged. The expansion drum 54 has a diameter that, as seen in plan, is smaller than an inner diameter of the opening Fa of the annular frame F and greater than an outer diameter of the wafer 10 bonded to the dicing tape T. The tape expanding units 52 in this embodiment are arranged as many as, for example, four around the expansion drum 54, and each include an air cylinder 52a fixed on the circular base 53, and a piston rod 52b extending upward from the air cylinder 52a and connected at an upper end thereof to a lower surface of the frame holding member 51a. To these air cylinders 52a, control air is supplied via communication paths (not illustrated). By operation of these air cylinders 52a, the piston rods 52b are extended or retracted in an up-down direction, so that the frame holding unit 51 is moved in the up-down direction.

The expansion unit 50 in this embodiment also includes, as illustrated in FIG. 3, a rotating mechanism that rotates the frame holding unit 51 together with the above-described expansion drum 54. The rotating mechanism 55 includes a pulse motor 55a (indicated by dashed lines) arranged on a side of the lower surface of the above-described second table 43, a rotating pulley mounted on a rotating shaft of the pulse motor 55a, and an endless belt 56 wrapped around the rotating pulley and the circular base 53. By driving the pulse motor of the rotating mechanism 55 configured as described above, the expansion unit 50 can be rotated a desired angle in a direction indicated by arrow R2 via the rotating pulley 55b and the endless belt 56.

The above-described pickup apparatus 40 is provided with position detection units (not illustrated) that detect a position in the Y-axis direction of the first table 42, a position in the X-axis direction of the second table 43, and an angular position in the rotating direction of the expansion unit 50. Based on position information detected by the position detection units, the first moving mechanism 44, the second moving mechanism and the rotating mechanism 55 are operated, so that the expansion unit 50 can be positioned at desired XY coordinate positions and angular position.

The detector 47 is means arranged on the base 41 for detecting and discriminating between the non-defective device chips 12a′ and defective device chips 12b′ divided individually from the wafer 10 that is supported via the dicing tape T on the annular frame F held on the frame holding unit 51. The detector 47 includes an L-shaped support column 47a arranged on the base 41 and an imaging unit 47b arranged on a distal end portion of the support column 47a. The detector 47 configured as described above images the non-defective device chips 12a′ and defective device chips 12b′ supported on the annular frame F that is held on the above-described frame holding unit 51, and the information so imaged is sent to a controller (not illustrated).

As illustrated in FIG. 3, the pickup instrument 48 is means arranged on the base 41 for drawing and extracting the individually divided non-defective device chips 12a′ and defective device chips 12b′ from the dicing tape T. The pickup instrument 48 includes a swing arm 48a arranged on the base 41 and a pickup collet 48b secured to a distal end of the swing arm 48a, and is configured such that the swing arm 48a is swung by a drive unit (not illustrated) in a direction indicated by arrow R3 and is also movable in an up-down direction indicated by arrow R4. To the pickup collet 48b, suction means (not illustrated) is connected. Each defective device chip 12b′ can be drawn to a distal end portion of the pickup collet 48b and can then be stored in a storage container 49 provided to store the defective device chips 12b′.

The pickup apparatus 40 generally has the configuration as described above. A description will hereinafter be made about procedures that perform the above-described defective device chip extracting step using the pickup apparatus 40.

The annular frame F, which supports the wafer 10 already subjected to the above-described providing step and dividing step, is first placed on the above-described frame holding member 51a and is fixed by the clamps 51b. At this time, as the frame holding member 51a has been raised by operation of the tape expanding units 52, the upper surface of the frame holding member 51a, on which the annular frame F is placed, is positioned at substantially the same height as an upper end edge of the expansion drum 54.

The first moving mechanism 44 and the second moving mechanism 45 are then operated to move the first table 42 in the Y-axis direction and also to adjust the position in the X-axis direction of the second table 43, so that the wafer 10 is positioned right below the imaging unit 47b of the detector 47. Next, the tape expanding units 52 are operated to lower the frame holding unit 51 in a direction indicated by arrow R5, so that the upper surface of the frame holding member 51a is lowered to a position lower than the upper end edge of the expansion drum 54. As a consequence, the dicing tape T is brought into contact with the upper end edge of the expansion drum 54 and is expanded radially, and therefore, the spacings between adjacent ones of the non-defective device chips 12a′ and defective device chips 12b′ are widened.

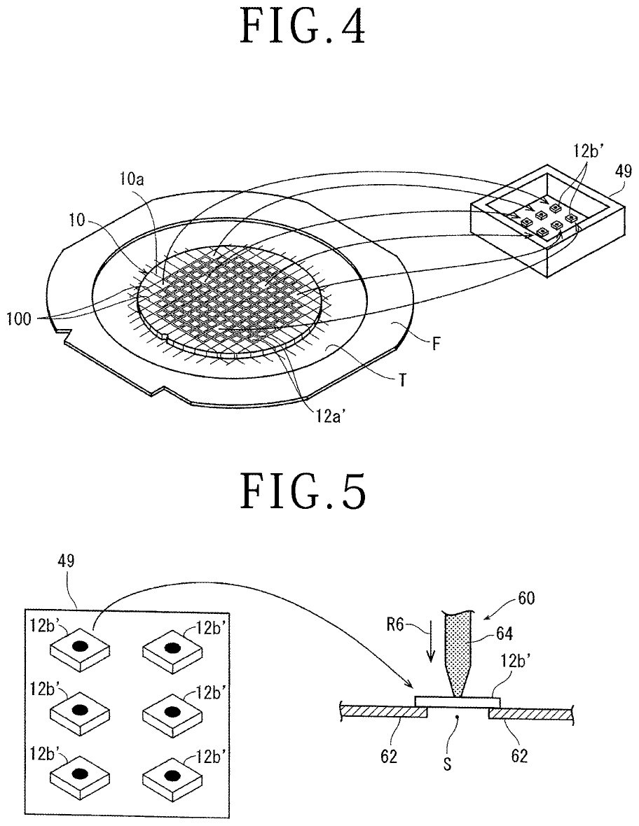

The above-described non-defective device chips 12a′ and defective device chips 12b′ are imaged by the imaging unit 47b, the defective device chips 12b′ that are defective in the electrical characteristic are discriminated from the non-defective device chips 12a′ based on the marking applied to the defective device chips 12b′, and their position information is acquired and then stored in the controller. Based on the position information, the first moving mechanism 44 and the second moving mechanism 45 are next operated, and the pickup instrument 48 is also operated. These operations are repeated to pick up only the defective device chips 12b′ one after another, so that, as illustrated in FIG. 4, all (six in this embodiment) the defective device chips 12b′ are stored in the storage container 49. Concurrently with the storage of the defective device chips 12b′, the non-defective device chips 12a′ may also be extracted and stored in another storage container. The defective device chip extracting step is not limited to the above-described method, and the defective device chips 12b′ may separately be collected, for example, by picking up and extracting the non-defective device chips 12a′ in advance from the wafer 10 and leaving the defective device chips 12b′ on the dicing tape T.

After the defective device chips 12b′ that are defective in the electrical characteristic have been extracted by performing the defective device chip extracting step as described above, a verification step is performed to verify a physical characteristic of each defective device chip 12b′ so extracted. The number of specimens required for the verification of the physical characteristic on the device chips divided from the wafer 10 should be determined through an experiment or the like conducted beforehand. Taking as a premise that six specimens are needed in this embodiment, this embodiment will hereinafter be described further although the number of necessary specimens differs depending on types of a wafer and devices.

As a specific method of the above-described verification step that verifies the physical characteristic, any desired one may be selected from a variety of methods as needed. Described typically, the flexural strength of each defective device chip 12b′ is verified by performing a three-point bending test in which a load is applied to the defective device chip 12b′ by using a physical strength measurement instrument 60 illustrated in a simplified form in FIG. 5. The physical strength measurement instrument 60 includes a pair of support mounts 62 arranged with a predetermined space S therebetween, and an indenter 64 to be centrally pressed from above toward the space S formed between the paired support mounts 62. The indenter 64 has such a tapered shape in cross-section that the thickness decreases toward a tip portion on a side of a lower end thereof, and is formed in a rounded shape at a tip portion thereof. The physical strength measurement instrument 60 also includes an indenter moving mechanism (not illustrated) that moves the indenter 64 in a direction indicated by arrow R6 in the figure, and a load cell (not illustrated) that measures a load applied to the indenter 64.

When performing the verification step, each defective device chip 12b′ is transferred to the above-described physical strength measurement instrument 60 and is placed on the paired support mounts 62 as illustrated on a right side in FIG. 5. Which one of a front surface or a back surface of the defective device chip 12b′ should be directed upward at this time is determined based on conditions of an experiment conducted beforehand upon setting of a reference value of flexural strength. When the indenter 64 is next gradually lowered from above and is brought into contact with the defective device chip 12b′, a load to be applied to the indenter 64 is measured by the above-described load cell. When the indenter 64 is lowered further, the indenter 64 is deformed and flexed downward. When the indenter 64 is lowered still further and the compression force exceeds a predetermined limit value, the defective device chip 12b′ is broken. Because of the breakage of the defective device chips 12b′, the load measured by the load cell abruptly decreases from the maximum value to zero. From variations in the measurement value of the load, the timing of the breakage of the defective device chip 12b′ and the maximum value of the load applied to the defective device chip 12b′ are hence determined. Based on the maximum value of the load, the distance of the space S between the paired support mounts 62, dimensions of the defective device chip 12b′, and the like, a bending stress value that is equivalent to the flexural strength of the defective device chip 12b′ is calculated. Such measurement of the physical strength is conducted on all the six defective device chips 12b′ extracted, and based on the results of the verification step, a determination step is next performed to determine whether or not the non-defective device chips 12a′ that are normal in the electrical characteristic should be transferred to a subsequent step.

In the determination step, a determination is made, for example, depending on whether or not the flexural strength (bending stress values) of all the above-described six defective device chips 12b′ satisfy the predetermined reference value. If the flexural strength of all the defective device chips 12b′ are determined to satisfy the reference value, it is determined that the non-defective device chips 12a′ that are normal in the electrical characteristic may all be sent to the subsequent step. If even only one of the defective device chips 12b′ is found to fail to satisfy the reference value as a result of the above-described verification step, on the other hand, it is determined that those which do not satisfy the reference value of the physical characteristic are included at a certain percentage in the non-defective device chips 12a′ that are normal in the physical characteristic, and that none of the non-defective device chips 12a′ should be transferred to the subsequent step.

According to the embodiment described above, the verification of the physical characteristic of the device chips divided from the wafer 10 is designed to be performed on the defective device chips 12b′ that have been determined to be defective in the electrical characteristic. It is therefore possible to avoid wasting of some of the non-defective device chips 12a′, and hence to eliminate the problem that the verification method of the related art is uneconomical. The number of the defective device chips 12b′ that are defective in the electrical characteristic differs depending on the fabricated wafer 10. If the number of the defective device chips 12b′ is smaller than the number (for example, 6) of necessary specimens, priority is given to the performance of the verification of the physical characteristic on the defective device chips 12b′ that are defective in the electrical characteristic, and the verification of the physical characteristic on only an insufficient number of ones out of the non-defective device chips 12a′ should then be performed. Even in this case, the number of the wasted non-defective device chips 12a′ can be limited to the minimum.

In the embodiment described above, the wafer 10 is transferred to the cutting apparatus 30 before performing the dividing step, and the wafer 10 is divided into the individual device chips by the cutting blade 34. However, the present invention is not limited to such a method and can adopt a variety of dividing methods. Examples include division by laser processing, division by etching that uses plasma, division by what is generally called dicing before grinding (DBG) in which grooves of a depth corresponding to a finish thickness are formed along streets on a front surface of a wafer and the wafer is then ground from a back surface thereof to expose the grooves, and division by what is generally called stealth dicing before grinding (SDBG) in which, after modified layers are formed inside a wafer by a laser beam, the wafer is ground from a back surface thereof and divided into individual device chips.

In the embodiment described above, described is the case in which the physical characteristic verified in the verification step is the flexural strength (bending stress value) of the device chips. However, the present invention is not limited to such a physical characteristic and may verify, for example, any one of conditions of chipping formed on an outer side of a front surface or a back surface, conditions of cracks formed on the front surface or the back surface, a finish thickness, dimensional variations, conditions of warping, or falling strength, or a combination of two or more of these physical characteristics.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A verification method for device chips, comprising:
a providing step of providing a wafer having a front surface with a plurality of devices formed thereon and demarcated by a plurality of intersecting streets, the devices including non-defective devices and defective devices that are distinguished from each other based on an electrical characteristic;
a dividing step of, after the providing step, dividing the wafer into individual device chips along the streets;
a defective device chip extracting step of extracting defective device chips from the individual device chips, the defective device chips corresponding to the defective devices and being defective in the electrical characteristic; and
a verification step of verifying a physical characteristic of each of the extracted defective device chips.

2. The verification method according to claim 1, further comprising:
a determination step of determining based on results of the verification step whether or not to transfer non-defective device chips out of the individual device chips to a subsequent step, the non-defective device chips corresponding to the non-defective devices and being non-defective in the electrical characteristic.

3. The verification method according to claim 1, wherein the wafer is positioned in an opening of an annular frame and is integrated with the annular frame via a dicing tape.

4. The verification method according to claim 1, wherein the dividing step is performed by one of a cutting blade, a laser beam, plasma, dicing before grinding, or stealth dicing before grinding.
